(19) United States
(12) Patent Application Publication
(10) Pub. No.: US 2020/0066766 A1
(43) Pub. Date: Feb. 27, 2020

(54) ARRAY SUBSTRATE AND MANUFACTURING METHOD THEREOF

(71) Applicant: Wuhan China Star Optoelectronics Semiconductor Display Technology Co., Ltd., Wuhan (CN)

(72) Inventor: Caiqin CHEN, Wuhan (CN)

(21) Appl. No.: 16/311,689

(22) PCT Filed: Sep. 7, 2018
(86) PCT No.: PCT/CN2018/104621

§ 371 Date: Dec. 20, 2018

(30) Foreign Application Priority Data
Aug. 22, 2018 (CN) 201810963274.9

(51) Int. Cl. H01L 27/12; H01L 29/786; H01L 29/66; G03F 7/16; G03F 7/20; G03F 7/26; G03F 1/32

(52) U.S. Cl. CPC H01L 27/1255; H01L 27/1222; H01L 27/124; H01L 29/78645; H01L 29/78675; H01L 27/3262; H01L 29/66757; G03F 7/16; G03F 7/20; G03F 7/26; G03F 1/32; H01L 27/1288

(57) ABSTRACT

An array substrate and a manufacturing method are provided in the present invention, including: providing a substrate with a patterned semiconductor layer; forming a gate insulating layer, a first gate electrode layer, a second gate insulating layer, and a capacitance metal layer on the semiconductor layer; and performing a photomask process to form a first gate electrode, a patterned second gate insulating layer, and a capacitance metal. Edges of the patterned second gate insulating layer are in flush contact with edges of the first gate electrode.

### 1. FIELD OF DISCLOSURE

The present invention relates to the field of display device techniques and in particular, to an array substrate and a manufacturing method thereof.

### 2. DESCRIPTION OF RELATED ART

At present, a thin-film transistor (TFT) is used to supply a driving current to a light emitting layer of an organic-light-emitting-diode (OLED) of an OLED display panel. By adjusting the current supplied from the TFT to the OLED, the brightness of the display panel is controlled appropriately.

Generally speaking, as shown in FIG. 1, an array substrate includes a first gate electrode 11 and a capacitance metal 12 disposed on the first gate electrode 11. The first gate electrode and the capacitance metal together constitute a capacitance of the array substrate. The capacitance is configured to store an action potential and a compensation potential at the array substrate.

The array substrate includes a poly-silicon layer, a first buffering layer, a first gate electrode layer, a capacitance metal layer, a second buffering layer and a capacitance metal layer overlapping each other. Patterning the first gate electrode layer and patterning the capacitance metal layer both include steps of depositing, developing, etching and removing. Due to these complicated steps, manufacturing the array substrate requires a longer production cycle. Hence, there is a strong demand to provide an array substrate and a manufacturing method thereof which can solve the above-mentioned problem.

### SUMMARY

The present invention provides an array substrate and a manufacturing method thereof to solve a problem in an array substrate. The problem is manufacturing the array substrate needs a long time since a first gate electrode and a capacitance metal layer each has a photomask process performed on them separately.

According to one aspect of the present invention, a manufacturing method of an array substrate is provided, comprising steps as follows:

Step S10: providing a substrate, the substrate including a patterned semiconductor layer;

Step S20: sequentially forming a first gate insulating layer, a first gate electrode layer, a second gate insulating layer, and a capacitance metal layer overlapping each other on the semiconductor layer; and

Step S30: performing a photomask process to pattern the first gate electrode layer, the second gate insulating layer, and the capacitance metal layer to form a first gate electrode, a patterned second gate insulating layer, and a capacitance metal, wherein edges of the patterned second gate insulating layer are in flush contact with edges of the first gate electrode.

According to one embodiment of the present invention, Step S30 comprises:

Step S301: coating a photoresist layer on the second gate insulating layer, the photoresist layer being exposed and developed through a predetermined mask;

Step S302: performing a first etching process on the first gate electrode layer, the second gate insulating layer and the capacitance metal layer; and

Step S303: removing the photoresist layer to form the first electrode, the patterned second gate insulating layer and the capacitance metal.

According to one embodiment of the present invention, Step S302 comprises: performing an ashing process on the photoresist layer for performing a second etching process on the capacitance metal layer to form a round hole in the capacitance metal.

According to one embodiment of the present application, the manufacturing method of the array substrate further comprises steps as follows:

Step S40: forming a planarization layer on the first gate insulating layer and forming a through hole in the planarization layer and the second gate insulating layer, the through hole being connected to the first gate electrode, the through hole passing through the round hole, the through hole being separated from the capacitance metal; and

Step S50: forming a signal metal on the planarization layer, the signal metal being electrically connected to the first gate electrode via the through hole.

According to one embodiment of the present application, the predetermined mask is a half-tone mask.

According to another aspect of the present invention, a manufacturing method of an array substrate is provided, comprising steps as follows:

S10: providing a substrate, the substrate including a patterned semiconductor layer;

S20: sequentially forming a gate insulating layer, a first gate electrode layer, a second gate insulating layer, and a capacitance metal layer on the semiconductor layer; and

S30: performing a photomask process to pattern the first gate electrode layer, the second gate insulating layer and the capacitance metal layer to form a first gate electrode, a patterned second gate insulating layer, and a capacitance metal, wherein edges of the patterned second gate insulating layer are in flush contact with edges of the first gate electrode.

According to one embodiment of the present invention, the Step S30 comprises:

Step S301: coating a photoresist layer on the second gate insulating layer, the photoresist layer being exposed and developed through a predetermined mask;

Step S302: performing a first etching process on the first gate electrode layer, the second gate insulating layer and the capacitance metal layer; and

Step S303: removing the photoresist layer to form the first electrode, the patterned second gate insulating layer and the capacitance metal.

According to one embodiment of the present invention, the Step S302 comprises:

performing an ashing process on the photoresist layer for performing a second etching process on the capacitance metal layer to form a round hole in the capacitance metal.

According to one embodiment of the present invention, the present invention further comprising:

Step S40: forming a planarization layer on the first gate insulating layer and forming a through hole in the planarization layer and the second gate insulating layer, the through hole being connected to the first gate electrode, the through hole passing through the round hole, the through hole being separated from the capacitance metal; and

Step S50: forming a signal metal on the planarization layer, the signal metal being electrically connected to the first gate electrode via the through hole.

According to one embodiment of the present invention, the predetermined mask is a half-tone mask.

According to another aspect of the present invention, an array substrate is provided. The array substrate includes a semiconductor layer, a first gate insulating layer disposed on the semiconductor layer, a first gate insulating layer disposed on the semiconductor layer, a first gate electrode disposed on the first gate insulating layer, a second gate insulating layer disposed on the first gate electrode, and a capacitance metal disposed on the second gate insulating layer, wherein edges of the second gate insulating layer are in flush contact with edges of the first gate electrode.

According to one embodiment of the present invention, a pattern size of the first gate electrode is the same as a pattern size of the capacitance metal.

According to one embodiment of the present invention, a pattern size of the first gate electrode is larger than a pattern size of the capacitance metal, and a round hole is disposed in the capacitance metal.

According to one embodiment of the present invention, the array substrate further comprising:

a planarization layer disposed on the first gate insulating layer, a through hole connected to the first gate electrode being disposed in the planarization layer and the second gate insulating layer, the through hole passing through the round hole, the through hole being separated from the capacitance metal; and

a signal metal disposed on the planarization layer, the signal metal being electrically connected to the first gate electrode via the through hole.

The present invention has the following advantages: The present invention provides the array substrate and the manufacturing method thereof. By changing the structure of the first gate insulating layer, the first gate electrode and the capacitance metal are manufactured in the same photomask process. The array substrate can be manufactured with improved efficiency, and the functionality of the array substrate is not compromised.

### BRIEF DESCRIPTION OF DRAWINGS

In order to more clearly illustrate the embodiments of the present disclosure or related art, figures which will be described in the embodiments are briefly introduced hereinafter. It is obvious that the drawings are merely for the purposes of illustrating some embodiments of the present disclosure, a person having ordinary skill in this field can obtain other figures according to these figures without an inventive work or paying the premise.

FIG. 1 is a schematic view showing a structure of a conventional array substrate;

FIG. 2 is a process flow diagram illustrating a manufacturing method of an array substrate according to one embodiment of the present invention;

FIGS. 3a to 3c are schematic structural views illustrating the manufacturing method of the array substrate according to one embodiment of the present invention;

FIG. 4 is a schematic structural view illustrating the array substrate in Step S302 according to another embodiment of the present invention;

FIG. 5 is a schematic structural view illustrating the array substrate in Step S40 according to another embodiment of the present invention;

FIG. 6 is a schematic structural view illustrating the array substrate in Step S50 according to another embodiment of the present invention; and

FIG. 7 is a schematic structural view illustrating the array substrate according to still another embodiment of the present invention.

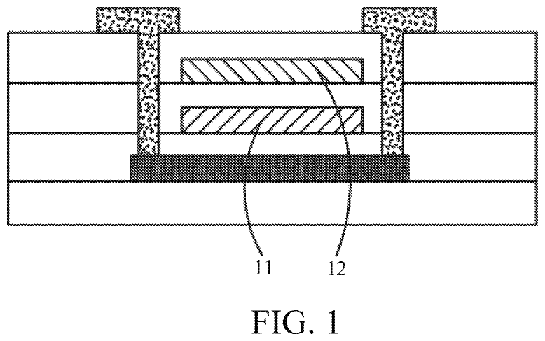

### DETAILED DESCRIPTION OF EMBODIMENTS

Embodiments of the present disclosure are described in detail with reference to the accompanying drawings as follows. Directional terms such as up/down, right/left and the like may be used for the purpose of enhancing a reader's understanding about the accompanying drawings, but are not intended to be limiting. Specifically, the terminologies in the embodiments of the present disclosure are merely for the purpose of describing certain embodiments, but not intended to limit the scope of the invention. The same reference numbers are used throughout the drawings to refer to the same or similar parts.

The present invention provides an array substrate and a manufacturing method thereof, so as to solve a problem existing in a conventional array substrate, which is the conventional array needs a long time to manufacture because multiple photomask processes are performed separately on a first gate electrode and a capacitance metal layer.

Detailed descriptions of the present disclosure and embodiments thereof are illustrated below in conjunction with the accompanying drawings.

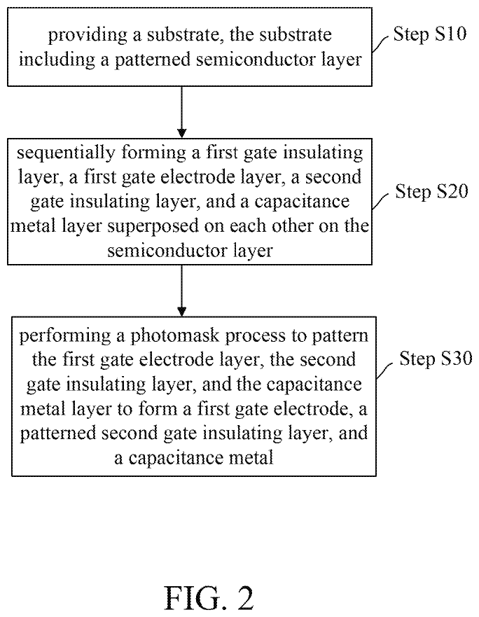

Referring to FIG. 2, FIG. 2 is a process flow diagram illustrating a manufacturing method of an array substrate according to one embodiment of the present invention. The manufacturing method of the array substrate comprises steps as follows.

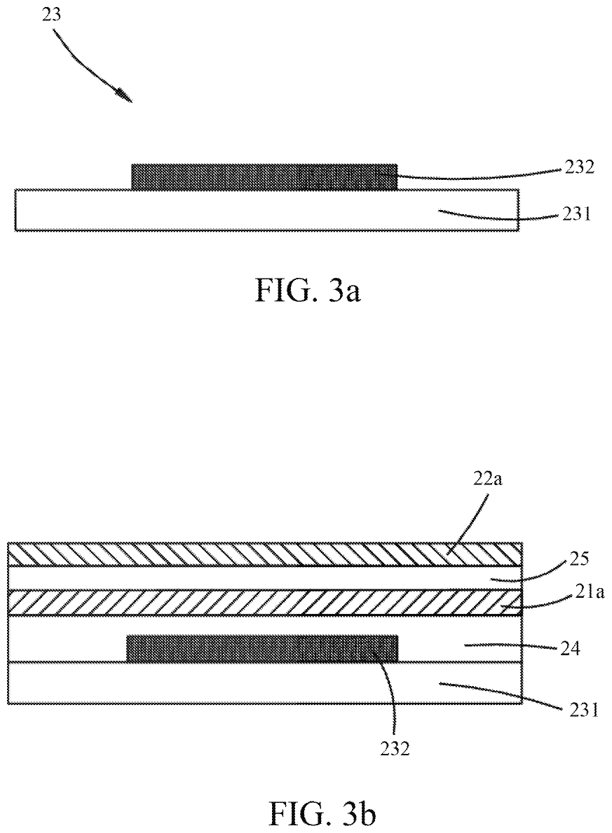

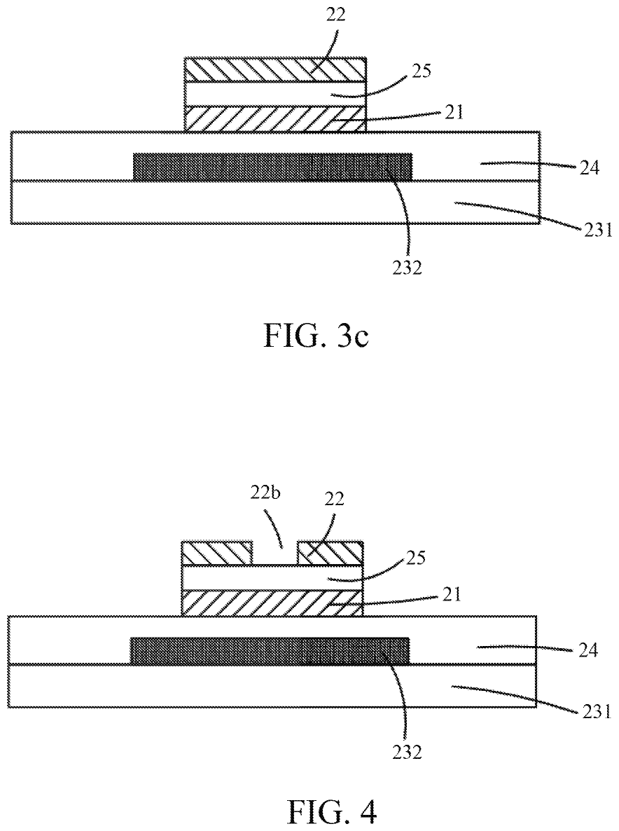

Referring to FIG. 3a, the manufacturing method of the array substrate comprises Step S10: providing a substrate 23, the substrate 23 including a patterned semiconductor layer 232.

According to one embodiment of the present invention, the substrate 23 includes a lining substrate 231 and a semiconductor layer 232 disposed on the lining substrate 231. It will be appreciated that, the lining substrate 231 can include a lining layer, an isolating layer, a light shielding layer and a buffering layer arranged in sequence.

According to one embodiment of the present invention, the semiconductor layer 232 is a poly-silicon layer. The poly-silicon layer usually includes a channel region in the middle and doped regions disposed at two ends corresponding to source and drain electrodes.

Referring to FIG. 3b, a first gate insulating layer 24, a first gate electrode layer 21a, a second gate insulating layer 25, and a capacitance metal layer 22a are sequentially formed on the semiconductor layer 232.

According to one embodiment of the present invention, the manufacturing method of the array substrate includes Step S20: sequentially forming a first gate insulating layer 24, a first gate electrode layer 21a, a second gate insulating layer 25, and a capacitance metal layer 22a overlapping each other on the semiconductor layer 232.

The array substrate including a capacitance metal 22 is usually used in an organic light-emitting diode (OLED) display panel, so as to form a storage capacitance with the first gate electrode, thereby ensuring that a stable electric potential signal can be obtained by the array substrate.

The first gate insulating layer 24 and the second gate insulating layer 25 are made of at least one of silicon dioxide and silicon nitride, so that the first gate electrode 21 and the capacitance metal 22 are electrically insulated from each other.

Referring to FIG. 3c, in Step S30, a photomask process is performed to pattern the first gate electrode layer 21a, the second gate insulating layer 25, and the capacitance metal layer 22a to form a first gate electrode 21, a patterned second gate insulating layer 25, and a capacitance metal 22.

According to one embodiment of the present invention, edges of the patterned second gate insulating layer 25 are in flush contact with edges of the first gate electrode 21. The structure configuration of the second gate insulating layer 25 allows the first gate electrode 21, the capacitance metal 22 and the second gate insulating layer 25 to be processed in the same photomask process.

According to one embodiment of the present invention, Step S30 includes:

Step S301: coating a photoresist layer on the second gate insulating layer 25, the photoresist layer being exposed and developed through a predetermined mask.

According to one embodiment of the present invention, the predetermined mask can be a half-tone mask or an ordinary mask according actual demands.

Step S302: performing a first etching process on the first gate electrode layer 21a, the second gate insulating layer 25 and the capacitance metal layer 22a; and

Step S303: removing the photoresist layer to form the first electrode 21, the patterned second gate insulating layer 25 and the capacitance metal 22.

The aforesaid embodiment is designed for the array substrate having the first gate electrode 21 and the capacitance metal 22 equally disposed, and there is no need to make a hole on the capacitance metal 22 or to have a structure for electrical connection.

Another embodiment of the present invention provides a manufacturing method of an array substrate, in which the structure of the array substrate has a through hole 27 on the capacitance metal for making electrical connection.

Please refer to FIG. 4 showing the structure of the array substrate in Step S302 of another embodiment of the present invention. Step S302 comprises: performing an ashing process on the photoresist layer for performing a second etching process on the capacitance metal layer 22a to form a round hole 22b in the capacitance metal 22. It should be noted that, the round hole 22b is formed in the capacitance metal 22, but the round hole 22b does not cut the capacitance metal 22 into two separate parts.

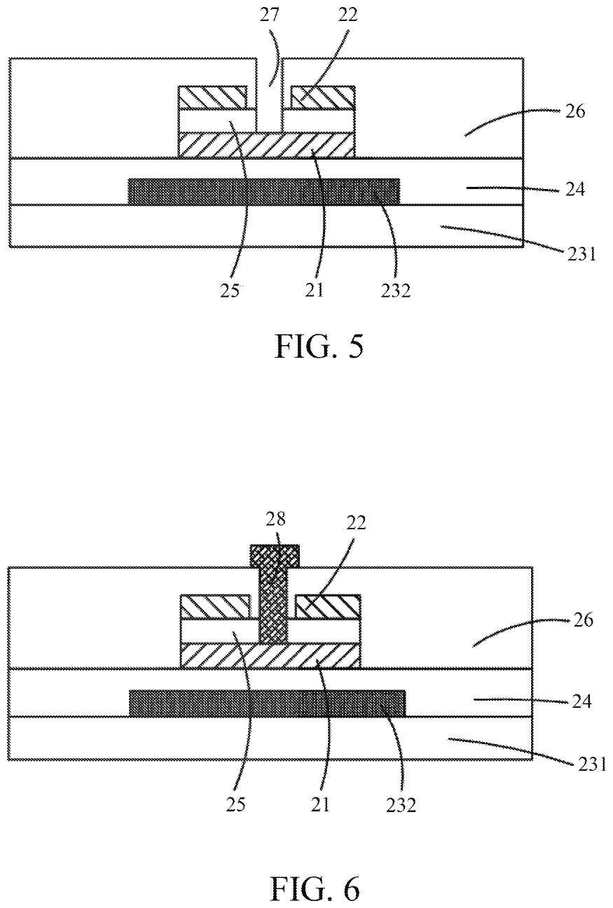

Please refer to FIG. 5, FIG. 5 shows the structure of the array substrate in Step S40 according to another embodiment of the present invention. According to another embodiment of the present invention, the manufacturing method of the array substrate further comprises Step S40.

Step S40: forming a planarization layer 26 on the first gate insulating layer 24 and forming a through hole 27 in the planarization layer 26 and the second gate insulating layer 25, the through hole 27 being connected to the first gate electrode 21, the through hole 27 passing through the round hole 22a, the through hole 27 being separated from the capacitance metal 22.

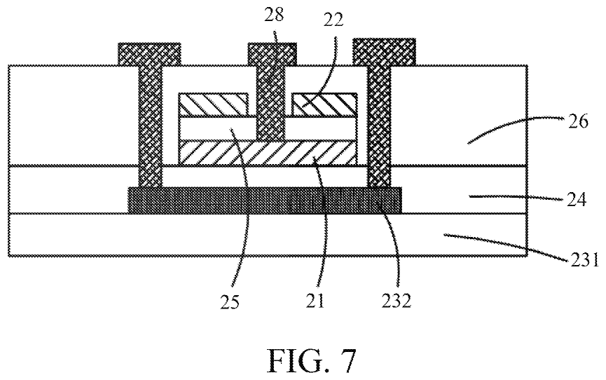

Please refer to FIG. 6, FIG. 6 shows the structure of the array substrate in Step S50 according to another embodiment of the present invention. Step S50: forming a signal metal 28 on the planarization layer 26, the signal metal 28 being electrically connected to the first gate electrode 21 via the through hole 27.

In one embodiment, the signal metal 28 is arranged at the same layer as the source and drain electrodes in the array substrate. Hence, there is no need to perform an extra process for manufacturing the signal metal 28. The signal metal 28 can be manufactured at the same time when the source and drain electrodes are manufactured.

The first gate electrode 21 and the signal metal 28 are electrically connected to each other via the through hole 27, so a signal of the first gate electrode 21 can be transmitted to other components of the array substrate.

In one embodiment, the manufacturing method of the array substrate includes steps of manufacturing the source and drain electrodes and other structure. These steps are prior art techniques, so a detailed description thereof is omitted herein for brevity.

According to another aspect of the present invention, an array substrate is provided. Please refer to FIG. 7, FIG. 7 shows the structure of the array substrate according to still another embodiment of the present invention. The array substrate includes a semiconductor layer 232, a first gate insulating layer 24 disposed on the semiconductor layer 232, a first gate electrode 21 disposed on the first gate insulating layer 24, a second gate insulating layer 25 disposed on the first gate electrode 21, and a capacitance metal 22 disposed on the second gate insulating layer 25, wherein edges of the second gate insulating layer 25 are in flush contact with edges of the first gate electrode 21.

According to one embodiment, a pattern size of the first gate electrode 21 is the same as a pattern size of the capacitance metal 22.

According to one embodiment of the present invention, a pattern size of the first gate electrode 21 is larger than a pattern size of the capacitance metal 22, and a round hole is disposed in the capacitance metal 22.

According to one embodiment of the present invention, the array substrate further comprises:

a planarization layer 26 disposed on the first gate insulating layer 24, a through hole 27 connected to the first gate electrode 21 being disposed in the planarization layer 26 and the second gate insulating layer 25, the through hole 27 passing through the round hole, the through hole 27 being separated from the capacitance metal 22, wherein the through hole 27 is in a place where a signal metal 28 is filled in the drawing; and

the signal metal 28 disposed on the planarization layer 26, the signal metal 28 being electrically connected to the first gate electrode 21 via the through hole.

The array substrate further comprises the commonly-used source and drain electrodes and other components.

The present invention has the following advantages. The present invention provides an array substrate and a manufacturing method thereof. By changing the structure of the first gate insulating layer, the first gate electrode and the capacitance metal are manufactured in the same photomask process. Accordingly, the array substrate can be manufactured efficiently, and the functionality of the array substrate is not compromised.

It is to be understood that the above descriptions are merely the preferable embodiments of the present invention and are not intended to limit the scope of the present invention. Equivalent changes and modifications made in the spirit of the present invention are regarded as falling within the scope of the present invention.

1. A manufacturing method of an array substrate, comprising steps of:
Step S10: providing a substrate, the substrate including a patterned semiconductor layer;
Step S20: sequentially forming a first gate insulating layer, a first gate electrode layer, a second gate insulating layer, and a capacitance metal layer overlapping each other on the semiconductor layer; and
Step S30: performing a photomask process to pattern the first gate electrode layer, the second gate insulating layer, and the capacitance metal layer to form a first gate electrode, a patterned second gate insulating layer, and a capacitance metal, wherein edges of the patterned second gate insulating layer are in flush contact with edges of the first gate electrode.

2. The manufacturing method of the array substrate according to claim 1, wherein Step S30 comprises:
Step S301: coating a photoresist layer on the second gate insulating layer, the photoresist layer being exposed and developed through a predetermined mask;
Step S302: performing a first etching process on the first gate electrode layer, the second gate insulating layer and the capacitance metal layer; and
Step S303: removing the photoresist layer to form the first electrode, the patterned second gate insulating layer and the capacitance metal.

3. The manufacturing method of the array substrate according to claim 2, wherein Step S302 comprises:
performing an ashing process on the photoresist layer for performing a second etching process on the capacitance metal layer to form a round hole in the capacitance metal.

4. The manufacturing method of the array substrate according to claim 3, comprising:
Step S40: forming a planarization layer on the first gate insulating layer and forming a through hole in the planarization layer and the second gate insulating layer, the through hole being connected to the first gate electrode, the through hole passing through the round hole, the through hole being separated from the capacitance metal; and
Step S50: forming a signal metal on the planarization layer, the signal metal being electrically connected to the first gate electrode via the through hole.

5. The manufacturing method of the array substrate according to claim 4, wherein the predetermined mask is a half-tone mask.

6. A manufacturing method of an array substrate, comprising steps as follows:
S10: providing a substrate, the substrate including a patterned semiconductor layer;
S20: sequentially forming a gate insulating layer, a first gate electrode layer, a second gate insulating layer, and a capacitance metal layer on the semiconductor layer; and
S30: performing a photomask process to pattern the first gate electrode layer, the second gate insulating layer and the capacitance metal layer to form a first gate electrode, a patterned second gate insulating layer, and a capacitance metal, wherein edges of the patterned second gate insulating layer are in flush contact with edges of the first gate electrode.

7. The manufacturing method of the array substrate according to claim 6, wherein Step S30 comprises:
Step S301: coating a photoresist layer on the second gate insulating layer, the photoresist layer being exposed and developed through a predetermined mask;
Step S302: performing a first etching process on the first gate electrode layer, the second gate insulating layer and the capacitance metal layer; and
Step S303: removing the photoresist layer to form the first electrode, the patterned second gate insulating layer and the capacitance metal.

8. The manufacturing method of the array substrate according to claim 7, wherein Step S302 comprises:
performing an ashing process on the photoresist layer for performing a second etching process on the capacitance metal layer to form a round hole in the capacitance metal.

9. The manufacturing method of the array substrate according to claim 8, further comprising:
Step S40: forming a planarization layer on the first gate insulating layer and forming a through hole in the planarization layer and the second gate insulating layer, the through hole being connected to the first gate electrode, the through hole passing through the round hole, the through hole being separated from the capacitance metal; and
Step S50: forming a signal metal on the planarization layer, the signal metal being electrically connected to the first gate electrode via the through hole.

10. The manufacturing method of the array substrate according to claim 8, wherein the predetermined mask is a half-tone mask.

11. An array substrate, comprising:
a semiconductor layer;
a first gate insulating layer disposed on the semiconductor layer;
a first gate electrode disposed on the first gate insulating layer;
a second gate insulating layer disposed on the first gate electrode; and
a capacitance metal disposed on the second gate insulating layer, wherein edges of the second gate insulating layer are in flush contact with edges of the first gate electrode.

12. The array substrate according to claim 11, wherein a pattern size of the first gate electrode is the same as a pattern size of the capacitance metal.

13. The array substrate according to claim 12, wherein a pattern size of the first gate electrode is larger than a pattern size of the capacitance metal, and a round hole is disposed in the capacitance metal.

14. The array substrate according to claim 13, further comprising:
a planarization layer disposed on the first gate insulating layer, a through hole connected to the first gate electrode being disposed in the planarization layer and the second gate insulating layer, the through hole passing through the round hole, the through hole being separated from the capacitance metal; and
a signal metal disposed on the planarization layer, the signal metal being electrically connected to the first gate electrode via the through hole.
